(19) United States
(12) Patent Application Publication
(10) Pub. No.: US 2013/0044453 A1
(43) Pub. Date: Feb. 21, 2013

(54) MOUNTING APPARATUS FOR POWER SUPPLY

(71) Applicants: HENG TAO, Wuhan City (CN); XUE-JIAO GUO, Wuhan City (CN); SHU-QIU WANG, Wuhan City (CN); ZHI-GUO ZHANG, Wuhan City (CN)

(72) Inventors: HENG TAO, Wuhan City (CN); XUE-JIAO GUO, Wuhan City (CN); SHU-QIU WANG, Wuhan City (CN); ZHI-GUO ZHANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/442,195

(22) Filed: Apr. 9, 2012

(30) Foreign Application Priority Data
Aug. 15, 2011 (CN) 201110232866.1

(51) Int. Cl. H05K 7/14

(52) U.S. Cl. 361/807

(57) ABSTRACT

An assembly comprises a chassis and a power supply installed on the chassis. The chassis comprises a bottom panel and a rear panel located on the bottom panel. A supporting plate is located on the bottom panel. The rear panel defines a through hole. A limiting piece and a positioning piece are located on the rear panel. The power supply is placed on the supporting plate. The power supply comprises a rear wall and two sidewalls located on two opposite sides of the rear wall. The rear wall defines an installation hole. A first distance between the limiting piece and the positioning piece is substantially equal to a second distance between the two sidewalls. The installation hole is aligned with the through hole when the power supply is located between the limiting piece and the positioning piece.

### BACKGROUND

1. Technical Field

The present disclosure relates to mounting apparatuses, particularly to a mounting apparatus for securing a power supply to a computer enclosure.

2. Description of Related Art

In a computer system, a power supply unit is usually provided and secured with a mounting apparatus. For example, a conventional mounting apparatus includes a chassis. The chassis includes a bottom panel and a rear panel connected to the bottom panel. The rear panel defines a plurality of through holes. A supporting plate is attached to the bottom panel. The power supply unit comprises a rear wall. The rear wall defines a plurality of installation holes corresponding to the through holes. In assembly, the power supply unit is placed on the supporting plate. The rear wall faces the rear panel and the power supply unit is moved. However, it is time consuming to align each of the installation holes with each of the through holes.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway, isometric view of an embodiment of a mounting apparatus and a power supply.

FIG. 2 is similar to the FIG. 1, but viewed from different aspect.

FIG. 3 is an assembled view of the mounting apparatus and the power supply of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

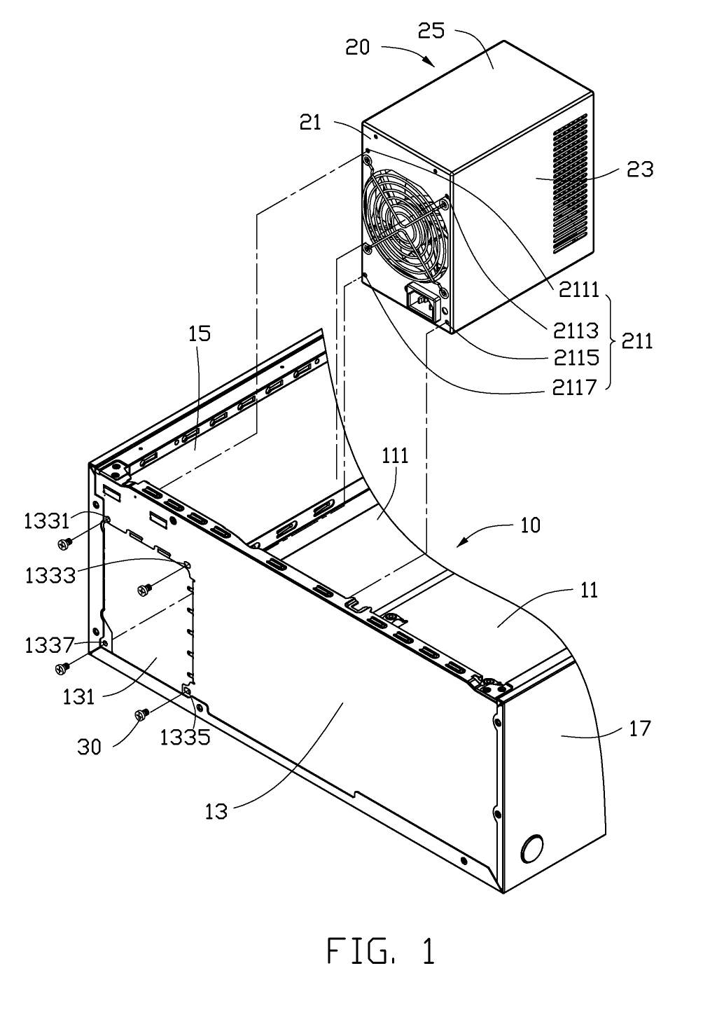

FIG. 1, is a mounting apparatus configured to secure a power supply 20 to a chassis 10.

The chassis 10 includes a bottom panel 11, a rear panel 13, a first side panel 15 and a second side panel 17. The rear panel 13 extends from the bottom panel 11 and is connected to the first side panel 15 and the second side panel 17. In one embodiment, the rear panel 13 is substantially perpendicular to the bottom panel 11. The first side panel 15 and the second side panel 17 extend from two opposite sides of the bottom panel 11. In one embodiment, the first side panel 15 is substantially perpendicular to the bottom panel 11, and the first side 15 is substantially parallel to the second side panel 17.

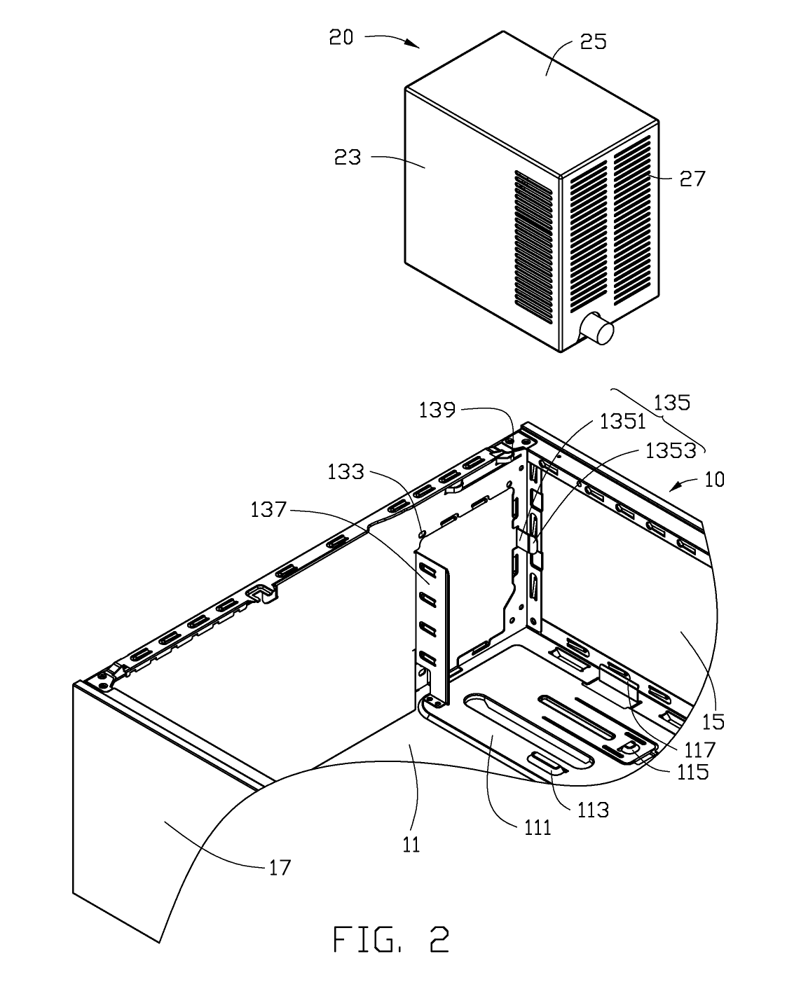

Referring to FIG. 2, a supporting plate 111 is located on the bottom panel 11. A protrusion 113 is located on the supporting plate 111. A stopping portion 115 protrudes from the supporting plate 111. A retaining piece 117 extends from the bottom panel 11 and is adjacent to the first side panel 15.

Referring to FIGS. 1-2, the rear panel 13 defines an opening 131 for dissipating heat generated from the power supply 20. Four through holes 133 are defined in the rear panel 13. In one embodiment, each of the four through holes 133 is arranged at four corners of a rectangular area. The four through holes 133 include a first through hole 1331, a second through hole 1333, a third through hole 1335 and a fourth through hole 1337. A first line is running through a center of the first through hole 1331 and a center of the second through hole 1333. A second line is running through a center of the third through hole 1335 and a center of the fourth through hole 1337. A third line is running through the center of the first through hole 1331 and the center of the fourth through hole 1337. A fourth line is running through the second through hole 1333 and the center of the third through hole 1335. In one embodiment, the first line is substantially parallel to the second line and a length of the first line is equal to a length of the second line; the third d line is substantially parallel to the fourth line, and a length of the third line is equal to a length of fourth line. A limiting piece 135 is located on the rear panel 13 adjacent to the first side panel 15. The limiting piece 135 includes a limiting portion 1351 and a guiding portion 1353. The limiting portion 1351 extends upward from a first edge of the opening 131. In one embodiment, the limiting portion 1351 is substantially perpendicular to the rear panel 13, and the limiting portion 1351 is substantially parallel to the first side panel 15. The guiding portion 1353 extends towards the first side panel 15 from a distal end of the limiting portion 1351. A positioning piece 137 extends from a second edge, opposite to the first edge of the opening 131. In one embodiment, the positioning piece 137 is substantially perpendicular to the rear panel 13, and the positioning piece is substantially parallel to the first side panel 15. Two blocking portions 139 are located on the rear panel 13 on the top of the opening 131. In one embodiment, each of the blocking portions 139 is substantially a V-shaped.

The power supply 20 includes a rear wall 21, a front wall 27 (shown in FIG. 2) parallel to the rear wall 21, two sidewalls 23 substantially parallel to each other, a top wall 25, a bottom wall (not shown) parallel to the top wall 25. The two sidewalls 23 are located on two opposite sides of the rear wall 21. In one embodiment, a first distance between the limiting piece 135 and the positioning piece 137 is substantially equal to a second distance between the two sidewalls 23.

The rear wall 21 defines four installation holes 211 corresponding to the four through holes 133. In one embodiment, the four installation holes 211 are arranged at four corners of a rectangular area. The four installation holes 211 include a first installation hole 2111, a second installation hole 2113, a third installation hole 2115 and a fourth installation hole 2117. A fifth line is running through a center of the first installation hole 2111 and a center of the second installation hole 2113. A sixth line is running through a center of the third installation hole 2115 and a center of the fourth installation hole 2117. A seventh line is running through a center of the first installation hole 2111 and a center of the fourth installation hole 2117. A eighth line is running through a center of the second installation hole 2113 and a center of the third installation hole 2115. In one embodiment, the fifth line is substantially parallel to the sixth line, and a length of the fifth line is equal to a length of the sixth line; the seventh line is substantially parallel and equal to the eighth line, and a length of the seventh line is equal to a length of the eighth line.

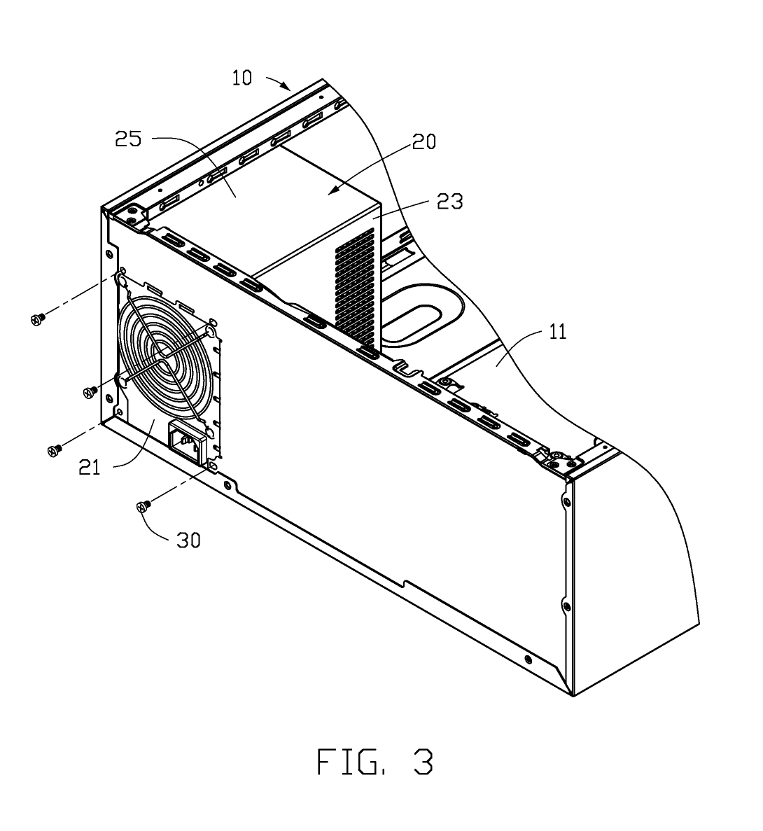

Referring to FIG. 3, in assembly, the power supply 20 is placed on the supporting plate 111 and located between the protrusion 113 and the retaining piece 117. The power supply 20 is moved in a first direction perpendicular to the rear panel 13, until one sidewall 23 abuts the positioning piece 137, another sidewall (not shown) abuts the limiting portion 1351, the rear wall 21 abuts the rear panel 13, the two blocking portions 139 abut the top wall 25, and the stopping portion 115 abuts the front wall 27 for the power supply 20 to move relative to the supporting plate 111. The four through holes 133 are aligned with the four installation holes 211. Four fixing members 30 are respectively inserted into the four through holes 133 and the four installation holes 1462, to mount the power supply 20 to the chassis 10. A first plane is defined by the positioning piece 137, a second plane is defined by the one sidewall 23 abutting the positioning piece 137, a third plane is defined by a top surface of the supporting plate 111, a fourth plane is defined by the bottom wall of the power supply. In one embodiment, a third vertical distance between the first through hole 1331 and the first plane is substantially equal to a fourth vertical distance between the first installation hole 2111 and the second plane, and a fifth vertical distance between the first through hole 2111 and the third plane is substantially equal to a sixth vertical distance between the first installation hole 2111 to the fourth plane.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An assembly comprising:
a chassis comprising a bottom panel and a rear panel connected to the bottom panel, a supporting plate located on the bottom panel, the rear panel defining a through hole, a limiting piece and a positioning piece located on the rear panel, a first distance defined between the limiting piece and the positioning piece; and
a power supply, the power supply comprising a rear wall and two sidewalls located on two opposite edges of the rear wall, the rear wall defining an installation hole, a second distance, defined between the two sidewalls, is substantially equal to the first distance;
wherein the installation hole is aligned with the through hole when the power supply is located on the supporting plate between the limiting piece and the positioning piece.

2. The assembly of claim 1, wherein the limiting piece comprises a limiting portion, and the limiting portion is substantially parallel to the positioning piece.

3. The assembly of claim 2, wherein the limiting portion and the positioning piece are substantially perpendicular to the rear panel.

4. The assembly of claim 1, wherein the rear panel defines an opening for dissipating heat generated from the power supply.

5. The assembly of claim 4, wherein the limiting piece and the positioning piece extend from two opposite edges of the opening.

6. The assembly of claim 5, wherein two blocking portions are located on the rear panel above the opening, the power supply further comprises a top wall connected to the rear wall, and the two blocking portions abut the top wall.

7. The assembly of claim 1, wherein one of the two sidewalls abuts the positioning piece, a first plane is defined by the positioning piece; a second plane is defined by the sidewall, which abuts the positioning piece; a third plane is defined by the supporting plate; a fourth plane is defined by a bottom wall of the power supply; a third vertical distance between a center of the through hole and the first plane is substantially equal to a fourth vertical distance between a center of the installation hole and the second plane; and
a fifth vertical distance between the through hole and the third plane is substantially equal to a sixth vertical distance between the installation hole and the four plane.

8. The assembly of claim 1, wherein a protrusion is located on the supporting plate, a retaining piece extends from the bottom panel, and the power supply is engaged between the protrusion and the retaining piece.

9. The assembly of claim 8, wherein the bottom panel defines a gap, and the retaining piece extends from one edge of the gap.

10. The assembly of claim 1, wherein a stopping portion protrudes from the supporting plate, the power supply further comprises a front wall parallel to the rear wall, and the stopping portion abuts the rear wall for preventing the power supply from moving along the supporting plate away from the rear panel.

11. An assembly comprising:
a chassis comprising a bottom panel and a rear panel located on the bottom panel, a supporting plate located on the bottom panel, a limiting piece and a positioning piece located on the rear panel; wherein the rear panel defines four through holes, and a first distance is defined between the limiting piece and the positioning piece; and
a power supply placed on the supporting plate, the power supply comprises a rear wall and two sidewalls located on two opposite sides of the rear wall, the rear wall defines four installation holes, and a second distance defined between the two sidewalls and substantially equal to the first distance;
wherein each of the four installation holes is aligned with a corresponding one of the four through holes when the power supply is located on the supporting plate between the limiting piece and the positioning piece.

12. The assembly of claim 11, wherein the limiting piece comprises a limiting portion, and the limiting portion is substantially parallel to the positioning piece.

13. The assembly of claim 12, wherein the limiting portion and the positioning piece are substantially perpendicular to the rear panel.

14. The assembly of claim 11, wherein the rear panel defines an opening for dissipating heat by generated by the power supply.

15. The assembly of claim 14, wherein two blocking portions are located on the rear panel on the top of the opening, the power supply comprises a top wall connected to the rear wall, and the two blocking portions abut the top wall.

16. The assembly of claim 11, wherein the four through holes comprise a first through hole, a second through hole, a third through hole and a fourth through hole; a first line connecting the first through hole and a second through hole is parallel to a second line connecting the third through hole and the fourth through hole, and a length of the first line is equal to a length of the second line; a third line connecting the first through hole and the fourth through hole is parallel to a fourth line connecting the second through hole and the third through, and a length of the third line is equal to a length of the fourth line.

17. The assembly of claim 16, wherein the four installation holes comprise a first installation hole, a second installation hole, a third installation hole and a fourth installation hole; a fifth line connecting the first installation hole and the second installation hole is substantially parallel to a sixth line connecting the third installation hole and the fourth installation hole, and a length of the fifth line is equal to a length of the sixth line; a seventh line connecting the first installation hole and the fourth installation hole is parallel to a eighth line connecting the second installation hole and the third installation hole, and a length of the seventh line is equal to a length of the eighth line.

18. The assembly of claim 17, wherein one of the two sidewalls abuts the positioning piece, a first plane is defined by the positioning piece; a second plane is defined by the sidewall, which abuts the positioning piece; a third plane is defined by the supporting plate; a fourth plane is defined by a bottom wall of the power supply; a third vertical distance between a center of the first through hole and the first plane is substantially equal to a fourth vertical distance between a center of the first installation hole and the second plane; and a fifth vertical distance between the first through hole and the third plane is substantially equal to a sixth vertical distance between the first installation hole and the four plane.

19. The assembly of claim 11, wherein a protrusion is located on the supporting plate, a retaining piece extends from the bottom panel, and the power supply is engaged between the protrusion and the retaining piece.

20. The assembly of claim 11, wherein a stopping portion protrudes from the supporting plate, the power supply comprises a front wall parallel to the rear wall, and the stopping portion abuts the rear wall for preventing the power supply from moving relative to the supporting plate.
